(19) United States
(12) Patent Application Publication
(10) Pub. No.: US 2022/0209495 A1
(43) Pub. Date: Jun. 30, 2022

(54) LASER DEVICE

(71) Applicant: Hisense Laser Display Co., Ltd, Qingdao City (CN)

(72) Inventors: Zinan ZHOU, Qingdao City (CN); Youliang TIAN, Qingdao City (CN); Guangchao DU, Qingdao City (CN); Jihong HAN, Qingdao City (CN)

(73) Assignee: Hisense Laser Display Co., Ltd, Qingdao City (CN)

(21) Appl. No.: 17/698,132

(22) Filed: Mar. 18, 2022

Related U.S. Application Data
(63) Continuation-in-part of application No. PCT/CN2020/121630, filed on Oct. 16, 2020.

(30) Foreign Application Priority Data
Sep. 20, 2019 (CN) 201910892473.X

(51) Int. Cl. H01S 5/02255; H01S 5/40; H01S 5/02326; H01S 5/02; H01S 5/02253; H01S 5/024

(52) U.S. Cl. CPC H01S 5/02255; H01S 5/4025; H01S 5/02469; H01S 5/0206; H01S 5/02253; H01S 5/02326

(57) ABSTRACT

A laser device includes a case, a support substrate, a plurality of laser chips and at least one prism which are located in the case. The plurality of laser chips and the at least one prism are all located on a side of the support substrate away from the case. The support substrate includes a chip mounting region where the plurality of laser chips are located, and a prism arrangement region where the at least one prism is located, the prism arrangement region being recessed toward the case relative to the chip mounting region. Each prism corresponds to one or more laser chips. Each prism is located on a light-emitting side of corresponding one or more laser chips, and each prism is configured to reflect a beam of light emitted by the corresponding one or more laser chips.

### CROSS-REFERENCE TO RELATED APPLICATIONS

This application is a continuation-in-part application of International Patent Application No. PCT/CN2020/121630 filed on Oct. 16, 2020, which claims priority to Chinese Patent Application No. 201910892473.X filed on Sep. 20, 2019. Both applications are incorporated herein by reference in their entireties.

### TECHNICAL FIELD

The present disclosure relates to the field of photoelectric technologies, and in particular, to a laser device.

### BACKGROUND

With the development of photoelectric technologies, laser devices also enjoyed rapid development. Laser devices are being used in more and more fields due to the purity and spectral stability of the light they emit. For example, laser devices may be used in the soldering process, cutting process, and laser projection.

### SUMMARY

A laser device is provided. The laser device includes a case, a support substrate, a plurality of laser chips and at least one prism. The support substrate is located in the case; the support substrate includes a chip mounting region and a prism arrangement region, and the prism arrangement region is recessed toward the case relative to the chip mounting region. The plurality of laser chips are located on a side of the support substrate away from the case, and located in the chip mounting region. The at least one prism is located on the side of the support substrate away from the case, and located in the prism arrangement region. Each prism corresponds to one or more laser chips. The prism is located on a light-emitting side of corresponding one or more laser chips, and the prism is configured to reflect a beam of light emitted by the corresponding one or more laser chips.

### BRIEF DESCRIPTION OF THE DRAWINGS

In order to describe technical solutions in the present disclosure more clearly, the accompanying drawings to be used in some embodiments of the present disclosure will be introduced briefly below. Obviously, the accompanying drawings to be described below are merely accompanying drawings of some embodiments of the present disclosure, and a person of ordinary skill in the art can obtain other drawings according to these drawings. In addition, the accompanying drawings to be described below may be regarded as schematic diagrams, and are not limitations on actual sizes of products, actual processes of methods and actual timings of signals involved in the embodiments of the present disclosure.

FIG. 1 is an exploded diagram of a laser device, in accordance with some embodiments;

FIG. 2 is a cross-sectional diagram of a laser device, in accordance with some embodiments;

FIG. 3 is a cross-sectional diagram of another laser device, in accordance with some embodiments;

FIG. 4 is a structural diagram of a laser device, in accordance with some embodiments;

FIG. 5 is a structural diagram of another laser device, in accordance with some embodiments;

FIG. 6A is a structural diagram of yet another laser device, in accordance with some embodiments;

FIG. 6B is a structural diagram of yet another laser device, in accordance with some embodiments;

FIG. 7 is a structural diagram of yet another laser device, in accordance with some embodiments; and

FIG. 8 is a structural diagram of yet another laser device, in accordance with some embodiments.

### DETAILED DESCRIPTION

Technical solutions in some embodiments of the present disclosure will be described clearly and completely below with reference to the accompanying drawings. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as an open and inclusive meaning, i.e., “including, but not limited to”. In the description, the terms such as “one embodiment”, “some embodiments”, “exemplary embodiments”, “example”, “specific example” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

In describing some embodiments, the terms “coupled”, “connected” and derivatives thereof may be used. For example, the term “connected” may be used when describing some embodiments to indicate that two or more components are in direct physical or electrical contact with each other. For another example, the term “coupled” may be used when describing some embodiments to indicate that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “applicable to” or “configured to” used herein has an open and inclusive meaning, which does not exclude devices that are applicable to or configured to perform additional tasks or steps.

In addition, the phrase “based on” used herein has an open and inclusive meaning, since a process, step, calculation or other action that is “based on” one or more of the stated conditions or values may, in practice, be based on additional conditions or values exceeding those stated.

As used herein, depending on the context, the term “if” is optionally construed as “when” or “in a case where” or “in response to determining” or “in response to detecting”. Similarly, depending on the context, the phrase “if it is determined . . . ” or “if [a stated condition or event] is detected” is optionally construed as “in a case where it is determined . . . ” or “in response to determining . . . ” or “in a case where [the stated condition or event] is detected” or “in response to detecting [the stated condition or event]”.

The phrase “at least one of A, B and C” has the same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

Hereinafter, the terms “first” and “second” are only used for descriptive purposes, and cannot be construed as indicating or implying the relative importance or implicitly indicating the number of indicated technical features. Therefore, a feature defined with “first” or “second” may explicitly or implicitly include one or more of the features. In the description of the embodiments of the present disclosure, the term “a plurality of/the plurality of” means two or more unless otherwise specified.

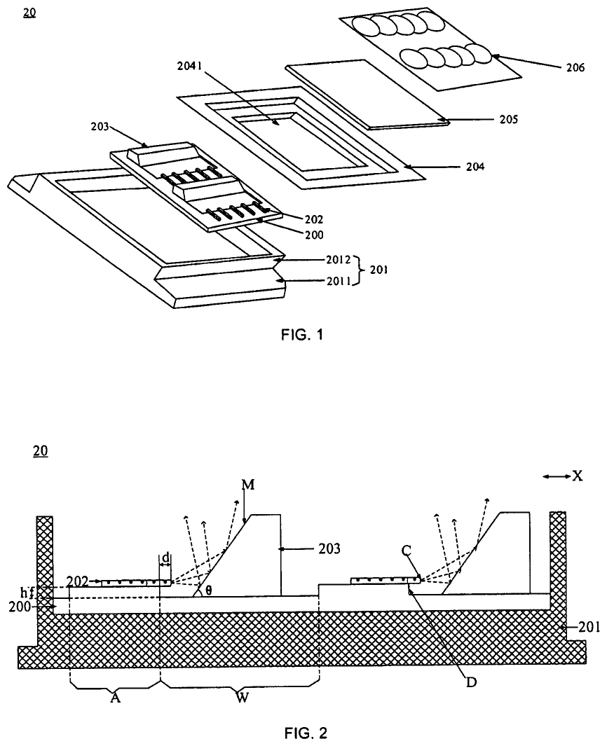

Some embodiments of the present disclosure provide a laser device. FIG. 1 is an exploded diagram of a laser device 20, in accordance with some embodiments. As shown in FIG. 1, the laser device 20 includes a case 201, a support substrate 200, a plurality of laser chips 202, at least one prism 203, a frame 204, a cover plate 205 and a collimating lens assembly 206. The support substrate 200 is located inside the case 201. The plurality of laser chips 202 and the at least one prism 203 are all located on a side of the support substrate 200 away from the case 201. The frame 204, the cover plate 205 and the collimating lens assembly 206 are stacked on the laser chip 202 in sequence along a direction away from the case 201.

The case 201 is configured to encapsulate the plurality of laser chips 202. The case 201 includes a base 2011 and an encapsulation portion 2012 disposed on the base 2011, and the encapsulation portion 2012 includes a hollow inner chamber.

In some embodiments, the support substrate 200, the plurality of laser chips 202 and the at least one prism 203 are all located in the inner chamber of the encapsulation portion 2012. The frame 204 covers the case 201, the cover plate 205 covers the frame 204, and the collimating lens assembly 206 covers the cover plate 205. The frame 204 has an opening 2041. In a case where the frame 204 covers the case 201, the plurality of laser chips 202 and the at least one prism 203 are exposed from the opening 2041. After the cover plate 205 covers the frame 204, the opening 2041 may be closed, and the inner chamber of the case 201 may be closed. The collimating lens assembly 206 includes a plurality of collimating lenses 2061, and the plurality of collimating lenses 2061 are in one-to-one correspondence with the plurality of laser chips 202.

Components of the laser device 20 are usually assembled by a heating and soldering method. If the thermal expansion coefficients of the components are all different, the soldering temperature needs to be reset in each assembling step according to a suitable heating temperature of each component. Therefore, in order to simplify the soldering process, in some embodiments, it is arranged that one or more of the frame 204, the cover plate 205 and the collimating lens assembly 206 have a same thermal expansion coefficient as the support substrate 200. For example, in a case where the thermal expansion coefficients of the components of the laser device 20 are all the same, the components may be assembled at the same temperature, which may speed up the assembly process of the laser device 20.

In the process of heating and soldering the components of the laser device 20 to assemble the components together, if the materials of the components are all different, it is difficult to solder the components together. Therefore, in some embodiments, it is arranged that one or more of the frame 204, the cover plate 205 and the collimating lens assembly 206 are made of a same material as the support substrate 200. For example, in a case where the materials of the components of the laser device 20 are all the same, the components may be more easily soldered into a one-piece structure during the heating and soldering process, which may help improve a firmness of the assembled laser device 20.

In some embodiments, the support substrate 200, the frame 204 and portions, other than the collimating lenses 2061, of the collimating lens assembly 206 are all made of ceramic. Ceramic has a high transmittance to infrared light. For a laser chip 202 that emits infrared light, the use of ceramic material may enable an even higher intensity of infrared light emitted by the laser device 20. In some embodiments, the cover plate 205 and the collimating lens 2061 are made of glass.

In some embodiments, a manufacturing process of the above laser device 20 is as follows: firstly, the case 201 is manufactured by using oxygen-free copper or kovar alloy (for example, iron-cobalt-nickel alloy); then, the support substrate is 200 is bonded to the case 201; and next, the plurality of laser chips 202 are soldered onto the support substrate 200 by using a high-precision eutectic soldering machine. It will be noted that, in a case where the support substrate 200 is not integrally formed with the at least one prism 203, there is a need to solder at least one prism 203 on the support substrate 200. After that, wires are formed in the case 201 by using a wire bonding machine, so that electrodes of the plurality of laser chips 202 are connected to corresponding power line terminals. Next, the cover plate 205 is soldered on the frame 204 by a parallel sealing technology. At last, alignment adjustment of the collimating lenses 2061 is completed through an alignment process, and then the collimating lens assembly 206 is fixed on the case 201 by an ultraviolet curing adhesive.

It will be noted that, in some embodiments, the frame 204, the cover plate 205 and the collimating lens assembly 206 are optional and can be omitted for the laser device 20.

FIG. 2 is a cross-sectional diagram of a laser device, in accordance with some embodiments. The present disclosure does not limit the number of the laser chips 202. For example, the laser device 20 may include two, three, four or even more laser chips 202.

The support substrate 200 includes: a chip mounting region where the plurality of laser chips 202 are located, and a prism arrangement region where the at least one prism 203 is located. The prism arrangement region is recessed relative to the chip mounting region (or, it may also be described as that the chip mounting region is protruding relative to the prism arrangement region). As shown in FIG. 2, compared with a portion of a surface of the support substrate 200 away from the case 201 located in the chip mounting region, a portion of the surface of the support substrate 200 away from the case 201 located in the prism arrangement region is closer to a surface of the support substrate 200 proximate to the case 201.

Each prism 203 may correspond to one or more laser chips 202. The prism 203 is located on a light-emitting side of corresponding one or more laser chips 202, and the prism 203 is configured to reflect a beam of light emitted by the corresponding one or more laser chips 202.

It will be noted that, in some embodiments of the present disclosure, a portion of the chip mounting region of the support substrate 200 that is protruding relative to the prism arrangement region of the support substrate 200 is equivalent to a heat sink. The heat sink is a cooling fin configured to transfer heat generated by the laser chip 202 when the laser chip 202 emits light to the case 201, so as to cool the laser chip 202. In some embodiments of the present disclosure, such an arrangement is equivalent to forming the heat sink and the support substrate 200 into a one-piece structure, so that there is no need to bond a heat sink to the support substrate 200. In this way, it may be possible to avoid a bonding error caused by bonding the heat sink, and reduce the assembling steps of the laser device 20.

In addition, in some embodiments of the present disclosure, the support substrate 200 itself may also be regarded as a heat sink with a relatively large thickness. As such, the heat generated by the plurality of laser chips 202 on the support substrate 200 when emitting light may be conducted in the support substrate 200 and travel in the support substrate 200 for a long time, so that the heat may be evenly distributed in the support substrate 200. Therefore, the heat generated by the plurality of laser chips 202 may be evenly dissipated; that is, the support substrate 200 may facilitate the heat dissipation of the plurality of laser chips 202.

In summary, in the laser device 20 provided by some embodiments of the present disclosure, the prism arrangement region of the support substrate 200 is recessed relative to the chip mounting region, and the plurality of laser chips 202 are located in the chip mounting region. Therefore, there is no need to bond a heat sink configured to support the plurality of laser chips 202 to the support substrate 200. Thus, it may be possible to avoid a bonding error caused by bonding the heat sink, reduce an overall manufacturing error of the laser device 20, and improve a collimation degree of the beam of light emitted by the laser device 20.

In some embodiments, a recess depth h of the prism arrangement region of the support substrate 200 relative to the chip mounting region may be greater than or equal to 2.5 μm and less than or equal to 5 μm. Since the beam of light emitted by the laser chip 202 has a divergence angle, if the recess depth h is less than 2.5 μm, the beam of light emitted by the laser chip 202 will be excessively directed toward a bottom of the prism 203 in the prism arrangement region, resulting in a waste of light. In a case where the recess depth h is greater than 2.5 μm, the laser chip 202 located in the chip mounting region may emit more light toward a middle or upper portion of the prism 203 in the prism arrangement region, thereby avoiding a waste of light and improving a brightness of the beam of light emitted by the laser device 20.

For example, the recess depth h of the prism arrangement region of the support substrate 200 relative to the chip mounting region may be 2.5 μm, 3 μm, 3.5 μm, 4 μm, 4.5 μm or 5 μm.

In some embodiments, the laser chip 202 may be soldered in the chip mounting region by a eutectic soldering method, or may be disposed in the chip mounting region by other methods (for example, bonding). The prisms 203 may be soldered in the prism arrangement region by a eutectic soldering method, or may be disposed in the prism arrangement region by other methods (for example, bonding).

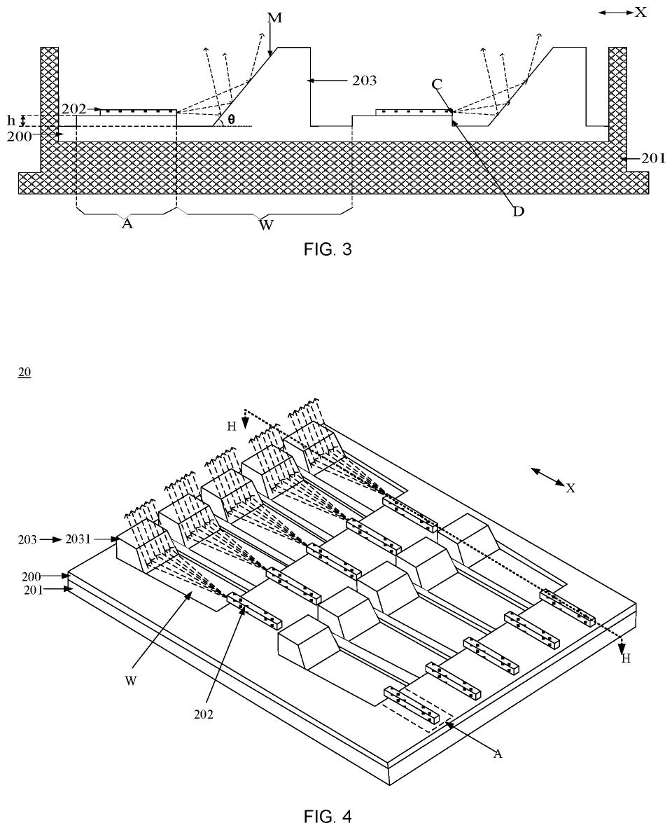

FIG. 3 is a cross-sectional diagram of another laser device, in accordance with some embodiments. As shown in FIG. 3, the prism 203 is integrally formed with the support substrate 200. Therefore, there is no need to solder or bond the prism 203 to the support substrate 200, which may avoid an error caused by soldering or bonding the prism 203, further reduce the overall manufacturing error of the laser device 20, and improve the collimation degree of the beam of light emitted by the laser device 20.

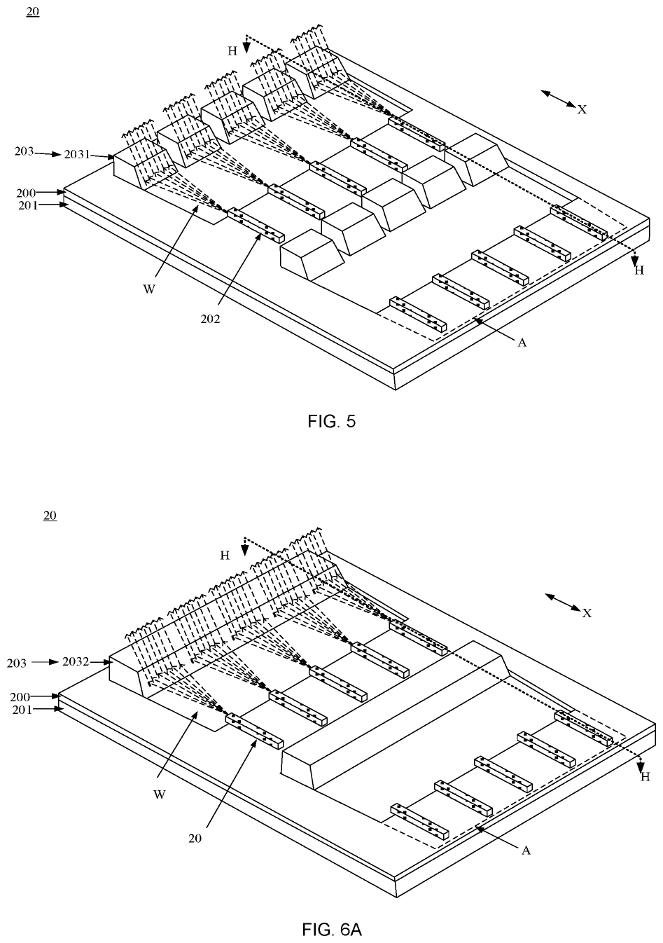

FIG. 4 is a structural diagram of a laser device, in accordance with some embodiments, and FIG. 2 may be regarded as a cross-sectional view taken along line H-H in FIG. 4. FIG. 5 is a structural diagram of another laser device, in accordance with some embodiments, and FIG. 3 may be regarded as a cross-sectional view taken along line H-H in FIG. 5. As shown in FIGS. 2 to 5, the chip mounting region of the support substrate 200 includes at least one sub-mounting region A, and the prism arrangement region includes at least one sub-arrangement region W. The at least one sub-mounting region A is in one-to-one correspondence with the at least one sub-arrangement region W, and the prism 203 located in the sub-arrangement region W corresponds to the laser chip 202 located in the sub-mounting region A corresponding to the sub-arrangement region W. The sub-mounting regions A and the sub-arrangement regions W are alternately arranged in a certain direction (e.g., the X direction in FIGS. 2 to 5), and a sub-mounting region A is adjacent to a corresponding sub-arrangement region W.

As shown in FIGS. 2 and 4, the chip mounting region of the support substrate 200 includes ten sub-mounting regions A, and the prism arrangement region of the support substrate 200 includes ten sub-arrangement regions W. In FIG. 4, each sub-mounting region A is indicated by a dashed box. Although FIG. 4 only shows a single dashed box, it will be understood that each laser chip 202 corresponds to a single sub-mounting region A. In some embodiments, every five adjacent sub-mounting regions A in FIG. 4 may be connected to each other to form a one-piece structure.

As shown in FIGS. 3 and 5, the chip mounting region of the support substrate 200 includes two sub-mounting regions A, and the prism arrangement region of the support substrate 200 includes two sub-arrangement regions W. In FIG. 5, each sub-mounting region A is indicated by a dashed box. Although FIG. 5 only shows a single dashed box, it will be understood that every five laser chips 202 correspond to a single sub-mounting region A.

For example, the number of the sub-mounting regions A and the number of the sub-arrangement regions W on the support substrate 200 may also be one, three, four or more. The present disclosure does not limit the number of the sub-mounting regions A and the number of the sub-arrangement regions W.

The prisms 203 located in the sub-arrangement region W and the laser chips 202 located in the sub-mounting region A corresponding to the sub-arrangement region W have two corresponding relations in terms of quantity.

In a first corresponding relation, each prism 203 of the at least one prism 203 of the laser device 20 corresponds to a single laser chip 202, and is configured to only reflect the beam of light emitted by a single laser chip 202.

In some embodiments, each sub-mounting region A has a single laser chip 202, each sub-arrangement region W corresponding to each sub-mounting region A has a single prism 203, and the prism 203 corresponds to the laser chip 202 of the sub-mounting region A corresponding to the sub-arrangement region W where the prism 203 is located.

As shown in FIG. 4, the laser device 20 includes ten laser chips 202 and ten prisms 203 in total; the chip mounting region of the support substrate 200 includes ten sub-mounting regions A, the prism arrangement region of the support substrate 200 includes ten sub-arrangement regions W, and the ten sub-mounting regions A are in one-to-one correspondence with the ten sub-arrangement regions W. Each sub-mounting region A has a single laser chip 202, each sub-arrangement region W has a single prism 203, and the single prism 203 corresponds to the single laser chip 202 of the sub-mounting region A corresponding to the sub-arrangement region W where the prism 203 is located; the single prism 203 is configured to reflect the beam of light emitted by the single laser chip 202 corresponding to the single prism 203.

In some other embodiments, each sub-mounting region A has a plurality of laser chips 202, and the sub-arrangement region W corresponding to each sub-mounting region A has a plurality of prisms 203; the number of the plurality of laser chips 202 is the same as the number of the plurality of prisms 203, and the plurality of laser chips 202 are in one-to-one correspondence with the plurality of prisms 203.

As shown in FIG. 5, the laser device 20 includes ten laser chips 202 and ten prisms 203 in total; the chip mounting region of the support substrate 200 includes two sub-mounting regions A, the prism arrangement region of the support substrate 200 includes two sub-arrangement regions W, and the two sub-mounting regions A are in one-to-one correspondence with the two sub-arrangement regions W. Each sub-mounting region A has five laser chips 202, and each sub-arrangement region W has five prisms 203. Each prism 203 corresponds to the laser chip 202 of the sub-mounting region A corresponding to the sub-arrangement region W where the prism 203 is located, and each prism 203 is configured to reflect the beam of light emitted by the single laser chip 202 corresponding to the prism 203.

It will be noted that, a structure of the base 2011 is omitted in FIGS. 4 and 5 in order not to block the components in the inner chamber of the encapsulation portion 2012 of the case 201. That is, the cross-sectional diagram shown in FIG. 2 may only be regarded as a cross-sectional view taken along the line H-H in FIG. 4, and cannot completely correspond to FIG. 4; the cross-sectional diagram shown in FIG. 3 may only be regarded as a cross-sectional view taken along the line H-H in FIG. 5, and cannot completely correspond to FIG. 5.

In some embodiments, the prism 203 in the first corresponding relation described above may be referred to as a first prism 2031.

In a second corresponding relation, the at least one prism 203 of the laser device 20 includes: a single prism 203 corresponding to the plurality of laser chips 202; and the single prism 203 may be configured to reflect beams of light emitted by the plurality of laser chips 202.

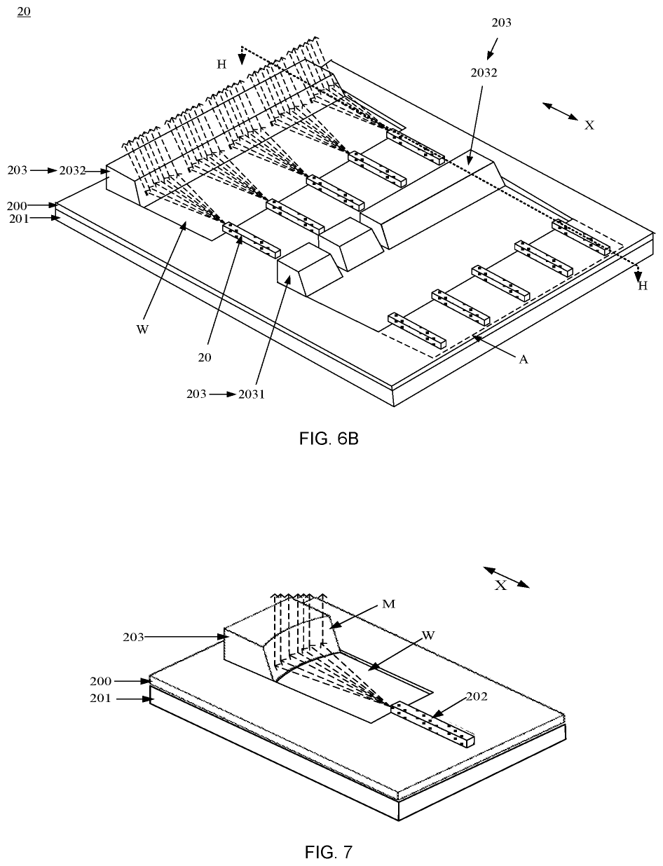

FIG. 6A is a cross-sectional diagram of yet another laser device, in accordance with some embodiments, and FIGS. 2 and 3 also may be regarded as cross-sectional views taken along line H-H in FIG. 6A. As shown in FIG. 6A, the laser device 20 includes ten laser chips 202 and two prisms 203 in total. The chip mounting region of the support substrate 200 includes two sub-mounting regions A, and the prism arrangement region of the support substrate 200 includes two sub-arrangement regions W. Each sub-arrangement region W is provided with a single prism 203; the single prism 203 corresponds to five laser chips 202 provided in the sub-mounting region A corresponding to the sub-arrangement region W where the single prism 203 is located, and the single prism 203 is configured to reflect beams of light emitted by the five laser chips 202.

In some embodiments, the prism 203 in the second corresponding relation described above may be referred to as a second prism 2032.

In some embodiments, the second prism 2032 may be in a shape of a strip. A length direction of the second prism 2032 is parallel to a direction in which the plurality of laser chips 202 are arranged, and is perpendicular to a direction in which each laser chip 202 emits light (e.g., the X direction shown in FIG. 6A).

In some other embodiments, as shown in FIG. 6B, the at least one prism 203 includes at least one first prism 2031 and at least one second prism 2032. Each first prism 2031 corresponds to a single laser chip 202, while each second prism 2032 corresponds to a plurality of laser chips 202.

The prism 203 provided in some embodiments of the present disclosure will be described below.

As shown in FIG. 2 or 3, in some embodiments, the prism 203 has a reflective surface M that faces the laser chip 202 corresponding to the prism 203, and the prism 203 reflects the beam of light emitted by the corresponding laser chip 202 through the reflective surface M.

For example, the reflective surface M may be a concave curved surface or an inclined surface. The reflective surface M is inclined in a direction moving away from the laser chip 202 corresponding to the prism 203 (the X direction in FIG. 2 or 3). That is, a bottom surface of the prism 203 proximate to the support substrate 200 is closer to the laser chip 202 than a top surface of the prism 203 away from the support substrate 200. FIGS. 2 and 3 illustrate a case where the reflective surface M is an inclined surface. An angle θ between the inclined surface and a board surface of the support substrate 200 may be 45 degrees. For example, in a case where the reflective surface M is a concave curved surface, the concave curved surface may be an aspherical surface, so that a curvature at each position of the concave curved surface is different. As a result, the beam of light emitted by the laser chip 202 reaching the concave curved surface may be converged into a relatively collimated beam of light.

FIG. 7 is a structural diagram of yet another laser device, in accordance with some embodiments. It will be noted that, FIG. 7 only shows a single laser chip 202 and a single prism 203 of the laser device 20, and does not show an entire structure of the case 201. In addition, FIG. 7 illustrates a case where the reflective surface M of the prism 203 of the support substrate 200 is a concave curved surface. As can be seen from FIG. 7, the beam of light emitted by the laser chip 202 reaching the reflective surface M may exit in a direction almost perpendicular to the board surface of the support substrate 200. As a result, the collimation degree of the beam of light emitted by the laser device 20 may be improved. In this case, the use of the collimating lens assembly 206 may be omitted, which facilitates a miniaturized design of the laser device 20.

For example, a maximum dimension of the prism 203 in a direction in which the prism 203 faces the corresponding laser chip 202 (e.g., the X direction in any one of FIGS. 2 to 7) ranges from 1.5 mm to 2.5 mm. For example, the maximum dimension is 1.5 mm, 1.8 mm, 2.0 mm, 2.1 mm, 2.4 mm or 2.5 mm. As shown in FIGS. 2 to 7, a dimension of the bottom surface of the prism 203 proximate to the support substrate 200 in this direction is the maximum dimension in this direction. As a result, a contact area between the prism 203 and the support substrate 200 is relatively large. Therefore, the prism 203 is disposed on the support substrate 200 more firmly with a smaller risk of damage.

For example, a height of the prism 203 ranges from 1 mm to 2 mm. For example, the height of the prism 203 is 1 mm, 1.2 mm, 1.5 mm, 1.6 mm, 1.8 mm or 2 mm.

In some embodiments of the present disclosure, the support substrate 200 has a good etchability. For example, the support substrate 200 has a high thermal conductivity, and the support substrate 200 may also be an insulating material. For example, the support substrate 200 is made of ceramic. Ceramic may include silicon materials such as silicon dioxide. Ceramic may also include aluminum oxide or aluminum nitride. For example, the material of the support substrate 200 is a transparent material. For example, a thickness of the support substrate 200 ranges from 4 mm to 7 mm; for example, the thickness of the support substrate 200 is 4 mm, 4.5 mm, 5 mm, 5.5 mm, 6 mm, 6.5 mm or 7 mm.

In some embodiments, an etching (such as dry etching or wet etching) technique may be used to pattern a ceramic plate-like structure or transparent plate-like structure, so as to obtain a support substrate 200 with the chip mounting region and the prism arrangement region. In some other embodiments, a mechanical grinding or ashing technique may be used to pattern a ceramic plate-like structure or transparent plate-like structure, so as to obtain a support substrate 200 with the chip mounting region and the prism arrangement region.

A positional relationship between the laser chip 202, the sub-mounting region A and the prism 203 in the laser device 20 provided by some embodiments of the present disclosure will be described below.

In some embodiments, as shown in FIG. 2, a first end C of any laser chip 202 of the laser device 20 extends beyond a second end D of the sub-mounting region A where the laser chip 202 is located, so as to be located between the second end of the sub-mounting region A where the laser chip 202 is located and the prism 203 corresponding to the laser chip 202; and a length d by which the first end C extends beyond the second end D of the sub-mounting region A is less than or equal to 15 μm. For example, the length d is 6 μm, 7 μm, 8 μm, 9 μm, 10 μm, 11 μm, 12 μm, 13 μm, 14 μm or 15 μm. For example, the length d may also be less than or equal to 5 μm. For example, the length d is 1 μm, 2 μm, 3 μm, 4 μm or 5 μm.

The first end C is an end of the laser chip 202 proximate to the prism 203, and the second end D is an end of the sub-mounting region A proximate to the prism 203. The X direction is the direction in which the laser chip 202 and the corresponding prisms 203 are arranged, and may also be considered as the light-emitting direction of the laser chips 202. It will be noted that, FIGS. 4 and 6A also illustrate an example where the first end C of the laser chip 202 extends beyond the second end D of the sub-mounting region where the laser chip 202 is located.

In some embodiments, as shown in FIG. 3, the first end C of any laser chip 202 of the laser device 20 is flush with the second end D of the sub-mounting region A where the laser chip 202 is located. It will be noted that, FIGS. 5 and 7 also illustrate an example where the first end C of the laser chip 202 is flush with the second end D of the sub-mounting region A where the laser chip 202 is located.

It will be noted that, the beam of light emitted by the laser chip 202 travels toward the corresponding prism 203, and then is reflected by the reflective surface M of the prism 203 and travels in a direction moving away from the case 201, so as to realize light emission of the laser device 20. Since the beam of light emitted by the laser chip 202 has a divergence angle, the light may reach a surface of the sub-arrangement region W. However, in a case where the first end C of the laser chip 202 is arranged to extend beyond the second end D of the sub-mounting region A, the amount of light emitted by the laser chip 202 reaching the surface of the sub-arrangement region W may be reduced, and the amount of light emitted by the laser chip 202 that is wasted may be reduced. Therefore, more light emitted by the laser chip 202 may reach the prism 203, and then be reflected and exit the laser device 20. In this case, the light emitted by the laser device 20 has a high brightness.

In a case where the support substrate 200 does not include the chip mounting region, but the laser device 20 has the heat sink and the laser chip 202 is located on the heat sink, since the heat sink itself has a certain thickness, if the thickness is large, although the light emitted by the laser chip 202 reaching the surface of the sub-arrangement region W is reduced, some light is directed toward the upper portion of the prism 203, resulting in a waste of light. Therefore, the first end C of the laser chip 202 needs to extend beyond the heat sink, and the length of a portion the laser chip 202 extending beyond the heat sink is usually greater than 15 μm, so that more light emitted by the laser chip 202 is directed toward the middle portion of the prism 203, and the brightness of light emitted by the laser device 20 is improved. Since the portion of the laser chip 202 extending beyond the heat sink cannot be attached to the heat sink, there is no support for the portion of the laser chip 202 extending beyond the heat sink. Moreover, since a large portion of the laser chip 202 extends beyond the heat sink, a stability of the laser chip 202 is poor. In addition, when the laser chip 202 emits light, the heat generated by the portion that is not attached to the heat sink cannot be conducted through the heat sink, resulting in a slow heat dissipation rate and in turn a poor heat dissipation effect of the laser chip 202.

In some embodiments of the present disclosure, the distance between the first end C of the laser chip 202 and the second end D of the sub-mounting region A where the laser chip 202 is located in the X direction is small (for example, the distance is less than or equal to 15 μm); and the first end C may also be flush with the second end D. With this arrangement, the contact area between the laser chip 202 and the support substrate 200 may be increased, so that the more or all regions of the laser chip 202 are supported, and the stability of the laser chip 202 is improved. In addition, when the laser chip 202 emits light, the heat generated in each region of the laser chip 202 may be conducted by the support substrate 200, and the heat dissipation effect of the laser chip 202 may be improved.

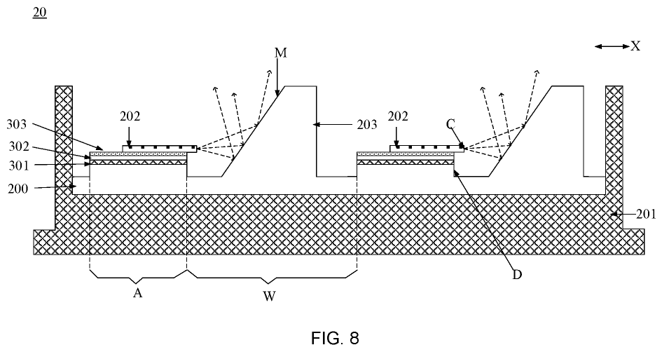

FIG. 8 is a structural diagram of yet another laser device, in accordance with some embodiments. As shown in FIG. 8, the laser device 20 further includes: a heat dissipation layer 301, an auxiliary layer 302 and a conductive layer 303 that are stacked in the chip mounting region of the support substrate 200 in sequence along a direction away from the case 201. The laser chip 202 is located on a side of the conductive layer 303 away from the case 201. An orthogonal projection of each of the heat dissipation layer 301, the auxiliary layer 302 and the conductive layer 303 on the support substrate 200 is located outside the prism arrangement region, and at least part of the orthogonal projection is located in the chip mounting region. It will be noted that, FIG. 8 illustrates an example where all orthogonal projections of the heat dissipation layer 301, the auxiliary layer 302 and the conductive layer 303 on the support substrate 10 are located within the chip mounting region, and FIG. 8 illustrates an example where the laser device 20 includes the support substrate 200 shown in FIG. 6A.

In some embodiments, the thermal conductivity of the heat dissipation layer 301 is greater than or equal to 20 W/(m·° C.). For example, the thermal conductivity of the heat dissipation layer 301 is 20 W/(m·° C.), 21 W/(m·° C.), 22 W/(m·° C.), 23 W/(m·° C.), 24 W/(m·° C.), or 25 W/(m·° C.). A material of the auxiliary layer 302 is different from a material of the heat dissipation layer 301, and is also different from a material of the conductive layer 303. The auxiliary layer 302 is configured to assist adhesion of the heat dissipation layer 301 to the conductive layer 303, thereby ensuring the adhesion reliability between the heat dissipation layer 301 and the conductive layer 104.

In some embodiments, a thermal expansion coefficient of the heat dissipation layer 301 may compatible with a thermal expansion coefficient of the support substrate 200. For example, an absolute value of a difference between the thermal expansion coefficient of the heat dissipation layer 301 and the thermal expansion coefficient of the support substrate 200 is less than or equal to 30×10⁻⁶/° C. In this way, it may be possible to prevent the difference between an expansion amount of the heat dissipation layer 301 and an expansion amount of the support substrate 200 from being too large when subjected to heat, and avoid a difference between the forces borne at each point of a contact surface between the heat dissipation layer 301 and the support substrate 200 from being too large. As such, it may be possible prevent a gap from appearing between the heat dissipation layer 301 and the support substrate 200, or prevent a wrinkle from appearing on the contact surface between the heat dissipation layer 301 and the support substrate 200, and thus ensure a firmness of the heat dissipation layer 301 on the support substrate 200.

In some embodiments, the absolute value of the difference between the thermal expansion coefficient of the heat dissipation layer 301 and the thermal expansion coefficient of the support substrate 200 is 30×10⁻⁶/° C., 29×10⁻⁶/° C., 28×10⁻⁶/° C., 27×10⁻⁶/° C., 26×10⁻⁶/° C. or 25×10⁻⁶/° C.

For example, the heat dissipation layer 301 is made of copper, and the thermal expansion coefficient thereof is 16.7×10⁻⁶/° C.; and the support substrate 200 is made of aluminum nitride, and the thermal expansion coefficient thereof is 4.5×10⁻⁶/° C.

In some embodiments, the thermal expansion coefficient of the heat dissipation layer 301 is the same as the thermal expansion coefficient of the support substrate 200. In this case, the heat dissipation layer 301 and the support substrate 200 have the same expansion amount when subjected to heat, and the force borne at each point of the contact surface between the heat dissipation layer 301 and the support substrate 200 is even. Therefore, it may be possible to further prevent a damage to an internal structure of the heat dissipation layer 301 or the support substrate 200, and improve the firmness of the heat dissipation layer 301 on the support substrate 200.

It will be noted that, the thermal conductivity and thermal expansion coefficient of the heat dissipation layer 301 need to be considered when determining a material of the heat dissipation layer 301. In a case where the thermal conductivity of the heat dissipation layer 301 is large with excellent thermal conductivity, a limitation on the thermal expansion coefficient of the heat dissipation layer 301 may be relaxed accordingly. For example, the absolute value of the difference between the thermal expansion coefficient of the heat dissipation layer 301 and the thermal expansion coefficient of the support substrate 200 may be set to be greater than 30×10⁻⁶/° C.

In some embodiments, the heat dissipation layer 301 is made of copper, and a thermal conductivity of copper may be 401 W/(m·° C.). In some other embodiments, the material of the heat dissipation layer 301 may include silver and/or aluminum. The auxiliary layer 302 may be made of nickel, and the conductive layer 303 may be made of gold.

Since the thermal conductivity of the heat dissipation layer 301 is large, the heat dissipation effect of the heat dissipation layer 301 is good. The heat generated when the laser chip 202 emits light may be rapidly conducted to the support substrate 200 through the conductive layer 303, the auxiliary layer 302 and the heat dissipation layer 301 in sequence, and then be dissipated. In this case, a temperature of the laser chip 202 may be rapidly reduced, which prevents the laser chip 202 from being damaged due to heat accumulation, and prolongs a service life of the laser chip 202.

In some embodiments, a thickness of the heat dissipation layer 301 may be greater than or equal to 1 μm. For example, the thickness of the heat dissipation layer 301 ranges from 30 μm to 75 μm. For example, the thickness of the heat dissipation layer 301 is 30 μm, 35 μm, 40 μm, 45 μm, 50 μm, 55 μm, 60 μm, 65 μm, 70 μm or 75 μm. Since the heat dissipation layer 301 is thick, the heat generated by the laser chip 202 may be conducted in the heat dissipation layer 301 and travel in the heat dissipation layer 301 for a long time, so that the heat is evenly distributed on the heat dissipation layer 301, and the heat generated by the laser chip 202 is evenly dissipated. In addition, since the heat dissipation layer 301 is thick, the amount of light emitted by the laser chip 202 reaching the surface of the support substrate 200 may be further reduced. That is, it may be possible to further prevent the waste of light and increase the brightness of the beam of light emitted by the laser device 20.

In summary, in the laser device 20 provided by some embodiments of the present disclosure, the prism arrangement region of the support substrate 200 is recessed relative to the chip mounting region, and the laser chip 202 is located in the chip mounting region. Therefore, there is no need to bond a heat sink configured for placing the laser chip 202 to the support substrate 200. Thus, it may be possible to avoid the bonding error caused by bonding the heat sink, reduce the overall manufacturing error of the laser device 20, and improve the collimation degree of the beam of light emitted by the laser device 20.

Finally, it will be noted that, the above embodiments are only used to illustrate the technical solutions of the present disclosure, but not to limit the same. Although the present disclosure are described in detail with reference to the foregoing embodiments, a person of ordinary skill in the art will understand that the technical solutions described in the foregoing embodiments may still be modified, or some of the technical features may be equivalently replaced, and these modifications or replacements do not deviate essences of corresponding technical solutions from the spirit and scope of the technical solutions of the embodiments of the present disclosure.

What is claimed is:

1. A laser device, comprising:
a case;
a support substrate located in the case, the support substrate including a chip mounting region and a prism arrangement region, and the prism arrangement region being recessed toward the case relative to the chip mounting region;
a plurality of laser chips located on a side of the support substrate away from the case, and located in the chip mounting region; and
at least one prism located on the side of the support substrate away from the case, and located in the prism arrangement region, each prism corresponding to one or more laser chips, each prism being located on a light-emitting side of corresponding one or more laser chips, and each prism being configured to reflect a beam of light emitted by the corresponding one or more laser chips.

2. The laser device according to claim 1, wherein
a recess depth of the prism arrangement region relative to the chip mounting region is greater than or equal to 2.5 μm and less than or equal to 5 μm.

3. The laser device according to claim 1, wherein
the at least one prism is integral with the support substrate.

4. The laser device according to claim 1, wherein
the chip mounting region includes at least one sub-mounting region, and the prism arrangement region includes at least one sub-arrangement region;
the at least one sub-mounting region is in one-to-one correspondence with the at least one sub-arrangement region, and each prism located in the sub-arrangement region corresponds to one or more laser chips located in the sub-mounting region corresponding to the sub-arrangement region; and
the at least one sub-mounting region and the at least one sub-arrangement region are alternately arranged in one direction, and each sub-mounting region is adjacent to a corresponding sub-arrangement region.

5. The laser device according to claim 4, wherein
each prism located in the sub-arrangement region corresponds to a single laser chip located in the sub-mounting region corresponding to the sub-arrangement region.

6. The laser device according to claim 4, wherein
each prism located in the sub-arrangement region corresponds to two or more of the laser chips located in the sub-mounting region corresponding to the sub-arrangement region.

7. The laser device according to claim 6, wherein
the prism is in a shape of a strip; a length direction of the prism is parallel to a direction in which the two or more of the laser chips are arranged, and is perpendicular to a direction in which the beam of light is emitted by each laser chip.

8. The laser device according to claim 4, wherein
at least one laser chip among the plurality of laser chips includes a first end flush with a second end of the sub-mounting region where the laser chip is located, wherein
the first end is an end of the at least one laser chip proximate to a prism corresponding to the at least one laser chip, and the second end is an end of the sub-mounting region where the at least one laser chip is located proximate to the prism corresponding to the at least one laser chip.

9. The laser device according to claim 4, wherein
at least one laser chip among the plurality of laser chips includes a first end extending beyond a second end of the sub-mounting region where the at least one laser chip is located, so as to be located between the second end of the sub-mounting region where the at least one laser chip is located and the prism corresponding to the at least one laser chip, wherein
the first end is an end of the at least one laser chip proximate to a prism corresponding to the at least one laser chip, and the second end is an end of the sub-mounting region where the at least one laser chip is located proximate to the prism corresponding to the at least one laser chip.

10. The laser device according to claim 9, wherein
a length by which the first end of the at least one laser chip extends beyond the second end of the sub-mounting region where the at least one laser chip is located is less than or equal to 15 μm.

11. The laser device according to claim 1, wherein
the support substrate is made of ceramic.

12. The laser device according to claim 1, further comprising: a frame, a cover plate and a collimating lens assembly that are stacked on a side of the plurality of laser chips away from the case in sequence along a direction away from the case, wherein
the frame covers the case, and the frame has an opening, so that the plurality of laser chips and the at least one prism are exposed from the opening;
the cover plate covers the frame to close the opening;
the collimating lens assembly covers the cover plate; the collimating lens assembly includes a plurality of collimating lenses, and the plurality of collimating lenses are in one-to-one correspondence with the plurality of laser chips.

13. The laser device according to claim 12, wherein
a thermal expansion coefficient of one or more of the frame, the cover plate and the collimating lens assembly is same as a thermal expansion coefficient of the support substrate.

14. The laser device according to claim 12, wherein
a material of one or more of the frame, the cover plate and the collimating lens assembly is same as a material of the support substrate.

15. The laser device according to claim 12, wherein
the case includes a base and an encapsulation portion disposed on the base; the encapsulation portion includes a hollow inner chamber; and the support substrate, the plurality of laser chips and the at least one prism are all disposed in the inner chamber.

16. The laser device according to claim 1, further comprising:
a heat dissipation layer, an auxiliary layer and a conductive layer that are stacked in the chip mounting region in sequence along a direction away from the case, the plurality of laser chips being located on a side of the conductive layer away from the case.

17. The laser device according to claim 16, wherein
a thermal conductivity of the heat dissipation layer is greater than or equal to 20 W/(m·° C.).

18. The laser device according to claim 16, wherein
an absolute value of a difference between a thermal expansion coefficient of the support substrate and a thermal expansion coefficient of the heat dissipation layer is less than or equal to 30×10⁻⁶/T.

19. The laser device according to claim 16, wherein a material of the heat dissipation layer includes copper; and
a material of the auxiliary layer is different from the material of the heat dissipation layer, and is also different from a material of the conductive layer.

20. The laser device according to claim 16, wherein a thickness of the heat dissipation layer is greater than or equal to 1 μm.
